(19) United States
(12) Patent Application Publication
(10) Pub. No.: US 2010/0039093 A1
(43) Pub. Date: Feb. 18, 2010

(54) CIRCUIT FOR GENERATING INTERNAL VOLTAGE OF SEMINCONDUCTOR MEMORY APPARATUS

(75) Inventors: YONG KEE KWON, Gyeonggi-do (KR); Hyung Dong Lee, Gyeonggi-do (KR)

Correspondence Address: VENABLE LLP, P.O. BOX 34385, WASHINGTON, DC, 20043-9998, US

(73) Assignee: Hynix Semiconductor Inc., Gyeonggi-do (KR)

(21) Appl. No.: 12/480,951

(22) Filed: Jun. 9, 2009

(30) Foreign Application Priority Data
Aug. 12, 2008 (KR) 10-2008-0078815

(51) Int. Cl. H03H 1/00

(52) U.S. Cl. 323/364

(57) ABSTRACT

An internal voltage generating circuit of a semiconductor memory apparatus includes a control signal generating unit configured to enable one of a plurality of control signals in response to a calibration code; and a signal variable voltage distributing unit configured to determine a distribution ratio in response to one enabled control signal of the plurality of control signals and generate an internal voltage by distributing an external voltage at the determined distribution ratio.

### CROSS-REFERENCES TO RELATED PATENT APPLICATION

The present application claims priority under 35 U.S.C 119(a) to Korean Application No. 10-2008-0078815, filed on Aug. 12, 2008, in the Korean Intellectual Property Office, which is incorporated herein by reference in its entirety as set forth in full.

### BACKGROUND

1. Technical Field

The embodiment described herein relates to a semiconductor memory apparatus and, more particularly, to a circuit for generating an internal voltage.

2. Related Art

In general, an internal voltage generating circuit of a semiconductor memory apparatus includes first to fifth resistance elements R1 to R5 and first to fourth fuses 11 to 14 as shown in FIG. 1.

An external voltage VDD is applied to one end of the first resistance element R1.

The other end of the first resistance element R1 is connected to one end of the second resistance element R2.

The other end of the second resistance element R2 is connected to one end of the third resistance element R3.

The other end of the third resistance element R3 is connected to one end of the fourth resistance element R4.

The other end of the fourth resistance element R4 is connected to one end of the fifth resistance element R5 and a ground terminal VSS is connected to the other end of the fifth resistance element R5.

A node that is connected to the first and second resistance elements R1 and R2 is connected to one end of the first fuse 11.

A node that is connected to the second and third resistance elements R2 and R3 is connected to one end of the second fuse 12.

A node that is connected to the third and fourth resistance elements R3 and R4 is connected to one end of the third fuse 13.

A node that is connected to the fourth and fifth resistance elements R4 and R5 is connected to one end of the fourth fuse 14. At this time, an internal voltage V_int is outputted from a node connected to the other ends of the first to fourth fuses 11 to 14.

An operation of the internal voltage generating circuit of the semiconductor memory apparatus will be described below.

When only the first fuse 11 is connected and the rest fuses 12 to 14 are cut among the first to fourth fuses 11 to 14, the internal voltage V_int dividing the external voltage VDD at a resistance distribution ratio of the first resistance element R1 and the second to fifth resistance elements R2 to R5 is outputted.

When only the second fuse 12 is connected and the rest fuses 11, 13, and 14 are cut among the first to fourth fuses 11 to 14, the internal voltage V_int dividing the external voltage VDD at a resistance distribution ratio of the first and second resistance elements R1 and R2 and the third to fifth resistance elements R3 to R5 is outputted.

When only the third fuse 13 is connected and the rest fuses 11, 12, and 14 are cut among the first to fourth fuses 11 to 14, the internal voltage V_int dividing the external voltage VDD at a resistance distribution ratio of the first to third resistance elements R1 to R3 and the fourth and fifth resistance elements R4 to R5 is outputted.

When only the fourth fuse 14 is connected and the rest fuses 11, 12, and 13 are cut among the first to fourth fuses 11 to 14, the internal voltage V_int dividing the external voltage VDD at a resistance distribution ratio of the first to fourth resistance elements R1 to R4 and the fifth resistance element R5 is outputted.

As described above, the internal voltage generating circuit of the semiconductor memory apparatus determines a voltage level of the internal voltage by cutting the fuses. In the internal voltage generating circuit, when a resistance value of the resistance element is changed depending on a change of process, voltage, and temperature (PVT) after cutting the fuses, the level of the internal voltage may be different from a designed level.

### SUMMARY

An internal voltage generating circuit of a semiconductor memory apparatus that can generate an internal voltage of a predetermined level in spite of variation in the P.V.T. by using a calibration code is disclosed herein.

In one embodiment of the invention, an internal voltage generating circuit of a semiconductor memory apparatus includes a control signal generating unit configured to enable one of a plurality of control signals in response to a calibration code; and a signal variable voltage distributing unit configured to determine a distribution ratio in response to one enabled control signal of the plurality of control signals and generate an internal voltage by distributing an external voltage at the determined distribution ratio.

These and other features, aspects, and embodiments are described below in the section “Detailed Description.”

### BRIEF DESCRIPTION OF THE DRAWINGS

Features, aspects, and embodiments are described in conjunction with the attached drawings, in which:

FIG. 1 is a block diagram schematically showing a configuration of a known internal voltage generating circuit of a semiconductor memory apparatus;

FIG. 2 is a block diagram schematically showing a configuration of an exemplary internal voltage generating circuit of a semiconductor memory apparatus according to one embodiment;

FIG. 3 is a configuration diagram of an exemplary control signal generating unit of FIG. 2 according to one embodiment; and

FIG. 4 is a configuration diagram of an exemplary signal variable voltage distributing unit of FIG. 2 according to one embodiment.

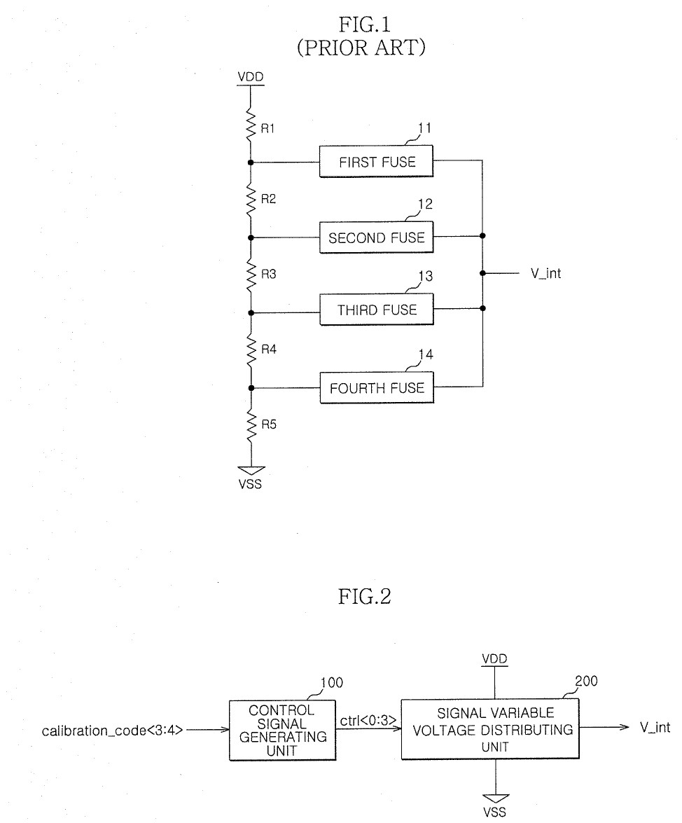

### DETAILED DESCRIPTION

An internal voltage generating circuit of a semiconductor memory apparatus according to one embodiment can be configured to include a control signal generating unit 100 and a signal variable voltage distributing unit 200 as shown in FIG. 2.

The control signal generating unit 100 can enable any one of first to fourth control signals ‘ctrl<0:3>’ in response to a calibration code ‘calibration_code<3:4>’. At this time, the calibration code ‘calibration_code<3:4>’ is generally used for a termination circuit, a data output driver, etc. of the semiconductor memory apparatus. The calibration code is generated to correct an internal impedance error of the semiconductor memory apparatus, which occurs due to variation in the P.V.T. (process, voltage, and temperature). In the present invention, 5-bit calibration codes ‘calibration_code<0:4>’ are exemplified. The present invention is implemented by using only upper 2-bit codes of the 5-bit calibration codes ‘calibration_code<0:4>’ in an embodiment, but is not limited thereto. In the disclosed embodiment of the present invention, the upper 2-bit codes of the 5-bit calibration codes ‘calibration_code<0:4>’ are assumed as the calibration code ‘calibration_code<3:4>’. The calibration code ‘calibration_code<3:4>’ can include a first calibration signal ‘calibration_code<3>’ and a second calibration signal ‘calibration_code<4>’.

The signal variable voltage distributing unit 200 can determine a distribution ratio in response to one enabled control signal ‘ctrl<i>’ of the first to fourth control signals ‘ctrl<0:3>’ and generate an internal voltage V_int by distributing an external voltage VDD at the determined distribution ratio.

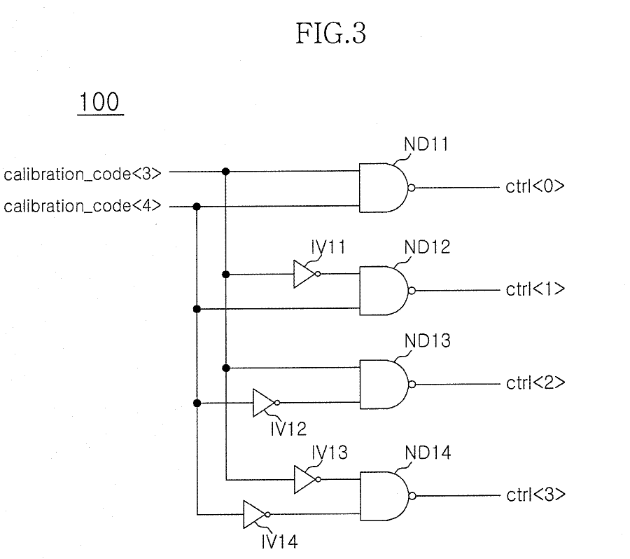

As shown in FIG. 3, the control signal generating unit 100 can be configured to include first to fourth inverters IV11 to IV14 and first to fourth NAND gates ND11 to ND14. The first inverter IV11 can receive the first calibration signal ‘calibration_code<3>’. The second inverter IV12 can receive the second calibration signal ‘calibration_code<4>’. The third inverter IV13 can receive the first calibration signal ‘calibration_code<3>’. The fourth inverter IV14 can receive the second calibration signal ‘calibration_code<4>’. The first NAND gate ND11 can output the first control signal ‘ctrl<0>’ by receiving the first and second calibration signals ‘calibration_code<3>’ and ‘calibration_code<4>’. The second NAND gate ND12 can output the second control signal ‘ctrl<1>’ by receiving an output signal of the first inverter IV11 and the second calibration signals ‘calibration_code<4>’. The third NAND gate ND13 can output the third control signal ‘ctrl<2>’ by receiving the first calibration signal ‘calibration_code<3>’ and an output signal of the second inverter IV12. The fourth NAND gate ND14 can output the fourth control signal ‘ctrl<3>’ by receiving output signals of the third and fourth inverters IV13 and IV14.

The control signal generating unit 100 can be implemented as a decoder that can selectively enable the first to fourth control signals ‘ctrl<0:3>’ in response to the first and second calibration signals ‘calibration_code<3:4>’.

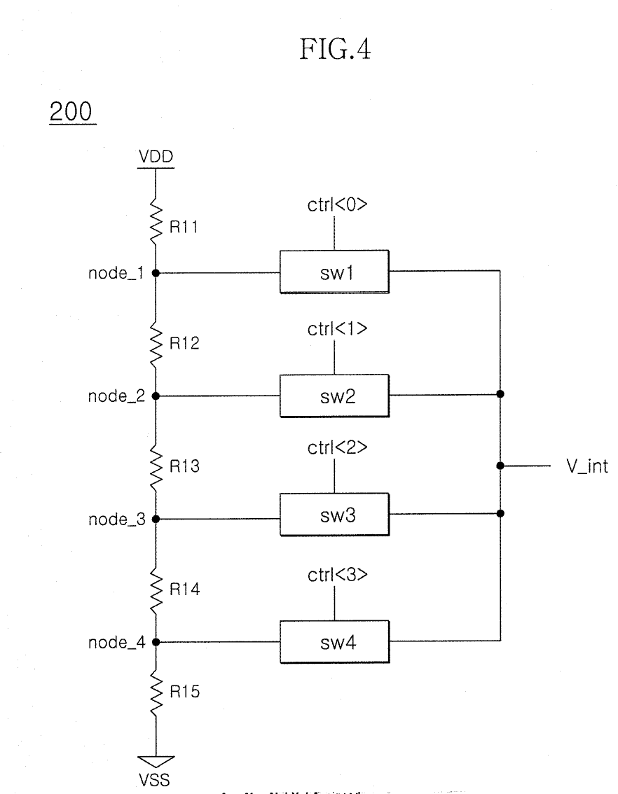

As shown in FIG. 4, the signal variable voltage distributing unit 200 can be configured to include first to fifth resistance elements R11 to R15 and first to fourth switching portions SW1 to SW4. The first to fifth resistance elements R11 to R15 can be connected to an external voltage terminal VDD and a ground terminal VSS in series. A node that is connected to the first resistance element R11 and the second resistance element R12 is referred to as a first node node_1. A node that is connected to the second resistance element R12 and the third resistance element R13 is referred to as a second node node_2. A node that is connected to the third resistance element R13 and the fourth resistance element R14 is referred to as a third node node_3. A node that is connected to the fourth resistance element R14 and the fifth resistance element R15 is referred to as a fourth node node_4.

The first switching portion SW1 is turned ON when the first control signal ‘ctrl<0>’ is enabled and outputs a voltage of the first node node_1 as the internal voltage V_int. The first node node_1 is connected to an input terminal of the first switching portion SW1 and the first control signal ‘ctrl<0>’ is inputted into a control terminal of the first switching portion SW1.

The second switching portion SW2 is turned ON when the second control signal ‘ctrl<1>’ is enabled and outputs a voltage of the second node node_2 as the internal voltage V_int. The second node node_2 is connected to an input terminal of the second switching portion SW2 and the second control signal ‘ctrl<1>’ is inputted into a control terminal of the second switching portion SW2.

The third switching portion SW3 is turned ON when the third control signal ‘ctrl<2>’ is enabled and outputs a voltage of the third node node_3 as the internal voltage V_int. The third node node_3 is connected to an input terminal of the third switching portion SW3 and the third control signal ‘ctrl<2>’ is inputted into a control terminal of the third switching portion SW3.

The fourth switching portion SW4 is turned ON when the fourth control signal ‘ctrl<3>’ is enabled and outputs a voltage of the fourth node node_4 as the internal voltage V_int. The fourth node node_4 is connected to an input terminal of the fourth switching portion SW4 and the fourth control signal ‘ctrl<3>’ is inputted into a control terminal of the fourth switching portion SW4. At this time, the internal voltage V_int is outputted from a node connected to output terminals of the first to fourth switching portions SW1 to SW4.

An operation of the exemplary internal voltage generating circuit of the semiconductor memory apparatus will be described below.

The calibration code ‘calibration_code<0:4>’ used in embodiments of the present invention are up-counted or down-counted for correcting an error depending on the variation in the P.V.T. of internal elements of the semiconductor memory apparatus. In the disclosed embodiment of the present invention, only the upper 2-bit codes ‘calibration_code<3:4>’ of the 5-bit calibration codes ‘calibration_code<0:4>’ are used.

When values of the 5-bit calibration codes ‘calibration_code<0:4>’ are (0, 0, 0, 0, 0) to (0, 0, 1, 1, 1), the first control signal ‘ctrl<0>’ is enabled. When the values of the 5-bit calibration codes ‘calibration_code<0:4>’ are (0, 1, 0, 0, 0) to (0, 1, 1, 1, 1), the second control signal ‘ctrl<1>’ is enabled. When the values of the 5-bit calibration codes ‘calibration_code<0:4>’ are (1, 0, 0, 0, 0) to (1, 0, 1, 1, 1), the third control signal ‘ctrl<2>’ is enabled. When the values of the 5-bit calibration codes ‘calibration_code<0:4>’ are (1, 1, 0, 0, 0) to (1, 1, 1, 1, 1), the fourth control signal ‘ctrl<3>’ is enabled. Therefore, upper 2-bit codes ‘calibration_code<3:4>’ of the 5-bit calibration codes ‘calibration_code<0:4>’ are used.

When the upper 2-bit codes ‘calibration_code<3:4>’ is (0, 0), the control signal generating unit 100 can enable the first control signal ‘ctrl<0>’ at a high level.

When the upper 2-bit codes ‘calibration_code<3:4>’ is (0, 1), the control signal generating unit 100 can enable the second control signal ‘ctrl<1>’ at a high level.

When the upper 2-bit codes ‘calibration_code<3:4>’ is (1, 0), the control signal generating unit 100 can enable the third control signal ‘ctrl<2>’ at the high level.

When the upper 2-bit codes ‘calibration_code<3:4>’ is (1, 1), the control signal generating unit 100 can enable the fourth control signal ‘ctrl<3>’ at the high level.

When the first control signal ‘ctrl<0>’ is enabled, the signal variable voltage distributing unit 200 can output the voltage of the first node node_1 as the internal voltage V_int.

When the second control signal ‘ctrl<1>’ is enabled, the signal variable voltage distributing unit 200 can output the voltage of the second node node_2 as the internal voltage V_int.

When the third control signal ‘ctrl<2>’ is enabled, the signal variable voltage distributing unit 200 can output the voltage of the third node node_3 as the internal voltage V_int.

When the fourth control signal ‘ctrl<3>’ is enabled, the signal variable voltage distributing unit 200 can output the voltage of the fourth node node_4 as the internal voltage V_int. At this time, it is possible to change the input relationship of the first to fourth control signals ‘ctrl<0:3>’ which are inputted into the first to fourth switching portions SW1 to SW4 constituting the signal variable voltage distributing unit 200 shown in FIG. 4. For example, the fourth control signal ‘ctrl<3>’, the third control signal ‘ctrl<2>’, the second control signal ‘ctrl<1>’ and the first control signal ‘ctrl<0>’ may be inputted into the first switching portion SW1, the second switching portion SW2, the third switching portion SW3, and the fourth switching portion SW4, respectively.

At this time, a voltage level of the first node node_1 is higher than a voltage level of the second node node_2, the voltage level of the second node node_2 is higher than a voltage level of the third node node_3, and the voltage level of the third node node_3 is higher than a voltage level of the fourth node node_4.

Consequently, embodiments of the present invention can control a level of an internal voltage by using a calibration code, which depends on the variation in the P.V.T. Accordingly, embodiments of the present invention have an advantage of improving operational reliability of the semiconductor memory apparatus by maintaining the level of the internal voltage constantly regardless of the change of P.V.T.

While certain embodiments have been described above, it will be understood to those skilled in the art that the embodiments described are by way of example only. Accordingly, the device and method described herein should not be limited based on the described embodiments. Rather, the apparatus described herein should only be limited in light of the claims that follow when taken in conjunction with the above description and accompanying drawings.

What is claimed is:

1. An internal voltage generating circuit of a semiconductor memory apparatus, comprising:
a control signal generating unit configured to enable one of a plurality of control signals in response to a calibration code to obtain an enabled control signal; and
a signal variable voltage distributing unit configured to determine a distribution ratio in response to the enabled control signal of the plurality of control signals and generate an internal voltage by distributing an external voltage at the distribution ratio.

2. The internal voltage generating circuit of claim 1, wherein the calibration code is 2-bit codes and the plurality of control signals include a first control signal, a second control signal, a third control signal, and a fourth control signal, and the control signal generating unit selectively enables the first to fourth control signals in response to the 2-bit codes to obtain the enabled control signal.

3. The internal voltage generating circuit of claim 2, wherein the control signal generating unit is a decoder.

4. The internal voltage generating circuit of claim 2, wherein the signal variable voltage distributing unit is configured to generate,
the internal voltage of a level when the first control signal is enabled lower than when the second control signal is enabled,
the internal voltage of the level when the second control signal is enabled lower than when the third control signal is enabled, and
the internal voltage of the level when the third control signal is enabled lower than when the fourth control signal is enabled.

5. The internal voltage generating circuit of claim 4, wherein the signal variable voltage distributing unit includes a first resistance element, a second resistance element, a third resistance element, a fourth resistance element, and a fifth resistance element, and
wherein the first to fifth resistance elements are connected to an external voltage terminal and a ground voltage terminal in series, and further including:
a first switching portion configured to output a voltage of a first node which is connected to the first and second resistance-elements as the internal voltage when the first control signal is enabled;
a second switching portion configured to output a voltage of a second node which is connected to the second and third resistance elements as the internal voltage when the second control signal is enabled;
a third switching portion configured to output a voltage of a third node which is connected to the third and fourth resistance elements as the internal voltage when the third control signal is enabled; and
a fourth switching portion configured to output a voltage of a fourth node which is connected to the fourth and fifth resistance elements as the internal voltage when the fourth control signal is enabled.

6. The internal voltage generating circuit of claim 2, wherein the signal variable voltage distributing unit is configured to generate,
the internal voltage of a level when the first control signal is enabled higher than when the second control signal is enabled,
the internal voltage of the level when the second control signal is enabled higher than when the third control signal is enabled, and
the internal voltage of the level when the third control signal is enabled higher than when the fourth control signal is enabled.

7. The internal voltage generating circuit of claim 6, wherein the signal variable voltage distributing unit includes a first resistance element, a second resistance element, a third resistance element, a fourth resistance element, and the fifth resistance element, and
wherein the first to fifth resistance elements are connected to an external voltage terminal and a ground voltage terminal in series, and further including:
a first switching portion configured to output a voltage of a first node which is connected to the first and second resistance elements as the internal voltage when the fourth control signal is enabled;
a second switching portion configured to output a voltage of a second node which is connected to the second and third resistance elements as the internal voltage when the third control signal is enabled;
a third switching portion configured to output a voltage of a third node which is connected to the third and fourth resistance elements as the internal voltage when the second control signal is enabled; and
a fourth switching portion configured to output a voltage of a fourth node which is connected to the fourth and fifth resistance elements as the internal voltage when the first control signal is enabled.

8. The internal voltage generating circuit of claim 1, wherein the calibration code is generated by a calibration circuit which is an internal circuit of the semiconductor memory apparatus in order to correct an internal impedance error of the semiconductor memory apparatus.
